(19) United States
(12) Patent Application Publication
(10) Pub. No.: US 2012/0212917 A1
(43) Pub. Date: Aug. 23, 2012

(54) Three-Dimensional Stack Structure Of Wafer Chip Using Interposer

(75) Inventors: Hyo Young Shin, Yongin-si (KR); Tae Sang Park, Seoul (KR); Young Jun Moon, Hwaseong-si (KR); Soon Min Hong, Seoul (KR)

(73) Assignee: SAMSUNG ELECTRONICS CO., LTD., Suwon-si (KR)

(21) Appl. No.: 13/402,267

(22) Filed: Feb. 22, 2012

(30) Foreign Application Priority Data
Feb. 23, 2011 (KR) 10-2011-0016038

(51) Int. Cl. H05K 7/02

(52) U.S. Cl. 361/767

(57) ABSTRACT

The three-dimensional stack structure includes a printed circuit board, a first wafer chip mounted on the printed circuit board, a second wafer chip stacked above the first wafer chip, and first interposers interposed between the second wafer chip and the printed circuit board. The first interposers are configured to electrically connect the second wafer chip to the printed circuit board.

### CROSS-REFERENCE TO RELATED APPLICATION

This application claims priority under 35 U.S.C. §119 to Korean Patent Application No. 2011-0016038, filed on Feb. 23, 2011 in the Korean Intellectual Property Office (KIPO), the entire contents of which are hereby incorporated by reference.

### BACKGROUND

1. Field

Embodiments relate to a three-dimensional stack structure of wafer chips using interposers to miniaturize small mobile products.

2. Description of the Related Art

In general, three-dimensional stack structures are used so as to mount a large number of wafer chips on a printed circuit board. These three-dimensional stack structures are divided into two types.

First, there is a package on package (POP) structure to three-dimensionally stack a plurality of packaged wafer chips through a surface mounting technology (SMT) process.

Second, there is a multi chip package (MCP) structure to three-dimensionally stack a plurality of wafer chips and then package the plurality of wafer chips. Here, in order to apply current to the wafer chips in the package, a gold wire bonding method and a through silicon via (TSV) forming method are used.

The above-described three-dimensional stack structures respectively have drawbacks, as follows.

In the POP structure, since the respective wafer chips are separately packaged, the area or thickness of the packaged unit is increased compared to the area or thickness of the wafer chip and packaging costs are increased.

Further, in the MCP structure, even if only one wafer chip within the packaged unit is defective, repair of such a defective wafer chip is difficult and thus other normal wafer chips within the packaged unit are not usable.

### SUMMARY

At least one embodiment provides a three-dimensional stack structure of wafer chips using interposers to achieve miniaturization of a printed board assembly (PBA).

Additional aspects of the embodiments will be set forth in part in the description which follows and, in part, will be obvious from the description, or may be learned by practice of the invention.

One embodiment of a three-dimensional stack structure of wafer chips includes a printed circuit board, a first wafer chip mounted on the printed circuit board, a second wafer chip stacked above the first wafer chip, and first interposers interposed between the second wafer chip and the printed circuit board. The first interposers are configured to electrically connect the second wafer chip to the printed circuit board.

The first wafer chip may be electrically connected to the printed circuit board by solder joints.

The second wafer chip may be electrically connected to the first interposers by solder joints.

The printed circuit board may include one of an Si wafer substrate, a glass substrate and a low CTE organic substrate.

The first interposers may be formed of at least one of flame retardant 4 (FR4), silicon (Si), an epoxy mold compound (EMC) and glass.

The first interposers may include conductive vias so as to electrically connect the second wafer chip to the printed circuit board.

The first interposers may be electrically connected to the printed circuit board by at least one of solder joints, a conductive adhesive and an anisotropic adhesive.

The first interposers may include solder balls.

The three-dimensional stack structure may further include a third wafer chip stacked above the second wafer chip, and second interposers interposed between the third wafer chip and the printed circuit board. The second interposers are configured to electrically connect the third wafer chip to the printed circuit board.

The third wafer chip may be electrically connected to the second interposers by solder joints.

The second interposers may be formed of at least one of flame retardant 4 (FR4), silicon (Si), an epoxy mold compound (EMC) and glass.

The second interposers may include conductive vias so as to electrically connect the third wafer chip to the printed circuit board.

The second interposers may be electrically connected to the printed circuit board by at least one of solder joints, a conductive adhesive and an anisotropic adhesive.

Another embodiment of a three-dimensional stack structure of wafer chips includes a printed circuit board, a first wafer chip mounted on the printed circuit board, first interposers mounted on the printed circuit board outside a periphery of the first wafer chip, and a second wafer chip mounted on the first interposers above the first wafer chip.

The three-dimensional stack structure may further include second interposers mounted on the printed circuit board outside a periphery of the first interposers, and a third wafer chip mounted on the second interposers above the second wafer chip.

### BRIEF DESCRIPTION OF THE DRAWINGS

Example embodiments will be more clearly understood from the following brief description taken in conjunction with the accompanying drawings. FIGS. 1-4 represent non-limiting, example embodiments as described herein.

FIG. 1 is a view illustrating a three-dimensional stack structure of wafer chips in accordance with one embodiment;

FIG. 2 is a view illustrating a three-dimensional stack structure of wafer chips in accordance with another embodiment;

FIG. 3 is a view illustrating a three-dimensional stack structure of wafer chips in accordance with another embodiment; and

FIG. 4 is a view illustrating a three-dimensional stack structure of wafer chips in accordance with a further embodiment.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

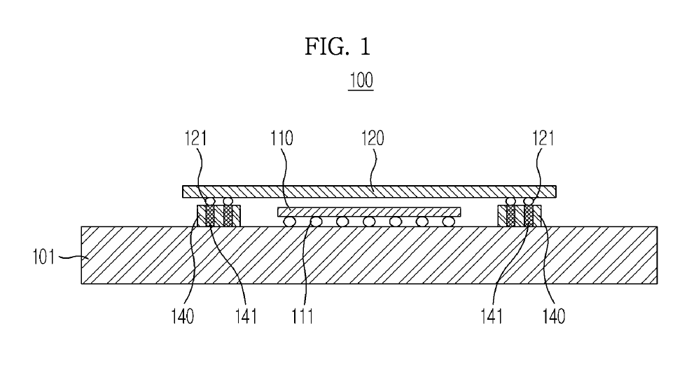

FIGS. 1 to 4 are views respectively illustrating three-dimensional stack structures of wafer chips in accordance with the embodiments.

Each of the three-dimensional stack structures of wafer chips in accordance with the example embodiments may use one of an Si wafer substrate, a glass substrate and a low CTE organic substrate as a printed circuit board 101, 201, 301 or 401 so as to improve reliability of the stack structures.

Further, interposers 140, 240, 340, 360, 440 and 460 may serve to achieve electrical connection between wafer chips 120, 220, 320, 330, 420 and 430 and may support the wafer chips 120, 220, 320, 330, 420 and 430, and may include no memory or no logic circuit.

First wafer chips 110, 210, 310 and 410 may be electrically connected to the printed circuit boards 101, 201, 301 and 401 by solder joints 111, 211, 311 and 411.

With reference to FIG. 1, a three-dimensional stack structure 100 of wafer chips in accordance with one example embodiment may include a printed circuit board 101, a first wafer chip 110 mounted on the printed circuit board 101, a second wafer chip 120 that may be located above the first wafer chip 110, and first interposers 140.

The first interposers 140 may be interposed between the second wafer chip 120 and the printed circuit board 101 so as to electrically connect the second wafer chip 120 to the printed circuit board 101 and to support the second wafer chip 120.

The first interposers 140 may be hollow structures, which may be mounted on the printed circuit board 101 so that the first wafer chip 110 may be located at the central area between the first interposers 140. Therefore, the first interposers 140 may be mounted on the printed circuit board 101 so as to be located outside a periphery of the first wafer chip 110.

The second wafer chip 120 may have a slightly greater size than the first wafer chip 110 and may be mounted on the upper surfaces of the first interposers 140.

The second wafer chip 120 may be electrically connected to the first interposers 140 by solder joints 121.

The first interposers 140 may be electrically connected to the printed circuit board 101 by at least one of solder joints, a conductive adhesive and an anisotropic adhesive.

The first interposers 140 may be formed of at least one of flame retardant 4 (FR4), silicon (Si), an epoxy mold compound (EMC) and glass.

The first interposers 140 include conductive vias 141 so as to electrically connect the second wafer chip 120 to the printed circuit board 101.

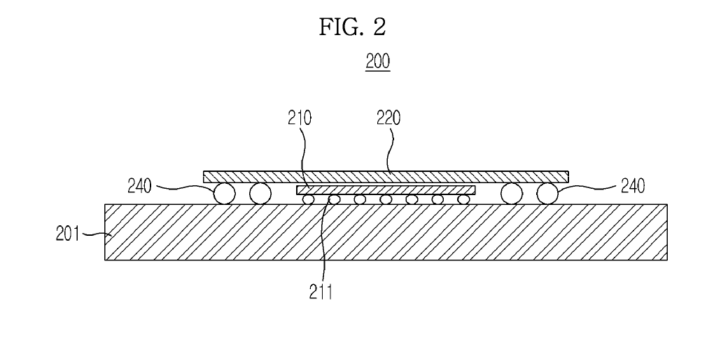

With reference to FIG. 2, a three-dimensional stack structure 200 of wafer chips in accordance with another example embodiment may include a printed circuit board 201, a first wafer chip 210 that may be mounted on the printed circuit board 201, a second wafer chip 220 that may be disposed above the first wafer chip 210, and first interposers 240.

Here, a plurality of conductive balls may be used as the first interposers 240. That is, solder that may be formed into the conductive balls may be used as the interposers 240.

The three-dimensional stack structure 200 in accordance with this example embodiment shown in FIG. 2 may be the same as the three-dimensional stack structure 100 in accordance with the earlier example embodiment shown in FIG. 1 except that the plurality of conductive balls may be used as the first interposers 240.

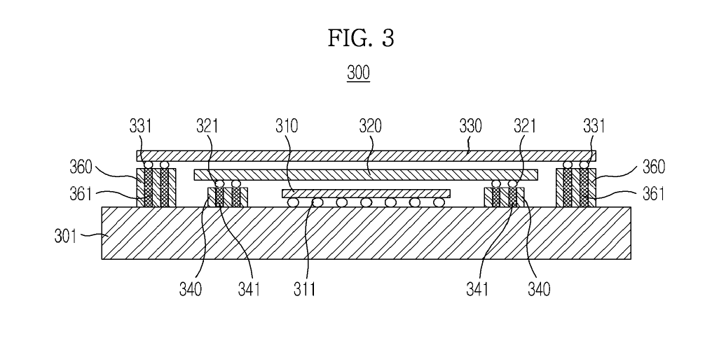

With reference to FIG. 3, a three-dimensional stack structure 300 of wafer chips in accordance with another example embodiment may include a printed circuit board 301, a first wafer chip 310 that may be mounted on the printed circuit board 301, a second wafer chip 320 that may be disposed above the first wafer chip 310, a third wafer chip 330 that may be disposed above the second wafer chip 320, first interposers 340 and second interposers 360. That is, the three-dimensional stack structure 300 in accordance with this example embodiment shown in FIG. 3 may include another stacked wafer chip compared to the three-dimensional stack structure 100 in accordance with the earlier example embodiment shown in FIG. 1.

The first interposers 340 may be interposed between the second wafer chip 320 and the printed circuit board 301 so as to electrically connect the second wafer chip 320 to the printed circuit board 301 and to support the second wafer chip 320.

The second interposers 360 may be interposed between the third wafer chip 330 and the printed circuit board 301 so as to electrically connect the third wafer chip 330 to the printed circuit board 301 and to support the third wafer chip 330.

The first interposers 340 may be hollow structures which may be mounted on the printed circuit board 301 so that the first wafer chip 310 may be located at the central area between the first interposers 340. Therefore, the first interposers 340 may be mounted on the printed circuit board 301 outside a periphery of the first wafer chip 310.

The second wafer chip 320 may have a slightly greater size than the first wafer chip 310 and may be mounted on the upper surfaces of the first interposers 340.

The second interposers 360 may be hollow structures which may be mounted on the printed circuit board 301 so that the first interposers 340 may be located at the central area between the second interposers 360. Therefore, the second interposers 360 may be mounted on the printed circuit board 301 outside a periphery defined by the first interposers 340.

The third wafer chip 330 may have a slightly greater size than the second wafer chip 320 and may be mounted on the upper surfaces of the second interposers 360.

The second wafer chip 320 may be electrically connected to the first interposers 340 by solder joints 321.

The third wafer chip 330 may be electrically connected to the second interposers 360 by solder joints 331.

The first interposers 340 and the second interposers 360 may be electrically connected to the printed circuit board 301 by at least one of solder joints, a conductive adhesive and an anisotropic adhesive.

Here, the thickness of the second interposers 360 may be greater than the thickness of the first interposers 340.

The first interposers 340 and the second interposers 360 may be formed of at least one of flame retardant 4 (FR4), silicon (Si), an epoxy mold compound (EMC) and glass.

The first interposers 340 include first conductive vias 341 so as to electrically connect the second wafer chip 320 to the printed circuit board 301.

The second interposers 360 include second conductive vias 361 so as to electrically connect the third wafer chip 330 to the printed circuit board 301.

Although this example embodiment illustrates that the three wafer chips 310, 320 and 330 may be stacked using the interposers 340 and 360 that may have different thicknesses, four or more wafer chips may be stacked through the same method.

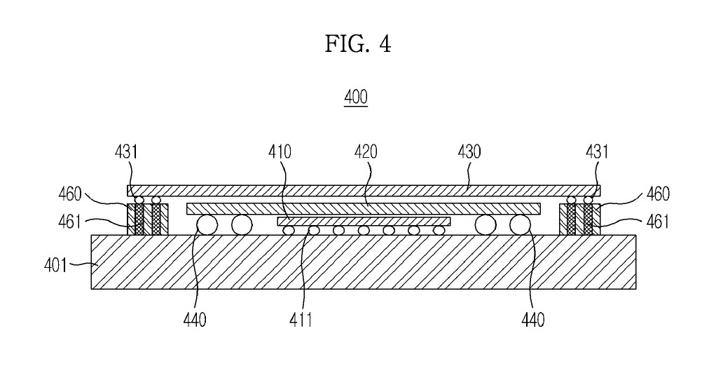

FIG. 4 is a view illustrating a three-dimensional stack structure of wafer chips in accordance with a further embodiment.

With reference to FIG. 4, a three-dimensional stack structure 400 of wafer chips in accordance with this example embodiment may include a printed circuit board 401, a first wafer chip 410 that may be mounted on the printed circuit board 401, a second wafer chip 420 that may be disposed above the first wafer chip 410, a third wafer chip 430 that may be disposed above the second wafer chip 420, first interposers 440 and second interposers 460.

Here, a plurality of conductive balls may be used as the first interposers 440. That is, solder that may be formed into the conductive balls may be used as the interposers 440.

The three-dimensional stack structure 400 in accordance with this example embodiment shown in FIG. 4 is the same as the three-dimensional stack structure 300 in accordance with the earlier example embodiment shown in FIG. 3 except that the plurality of conductive balls may be used as the first interposers 440.

That is, the third wafer chip 430 may be electrically connected to the second interposers 460 by solder joints 431. Further, the second interposers 460 include conductive vias 461 so as to electrically connect the third wafer chip 430 to the printed circuit board 301.

As is apparent from the above description, a three-dimensional stack structure of wafer chips using interposers in accordance with one example embodiment may not require separate packaging of the respective wafer chips, thus possibly preventing an increase in area and thickness due to packaging. Therefore, the size of a printed board assembly (PBA) may be reduced.

Further, packaging and repair processes may be simplified, thus achieving cost reduction.

Moreover, a range of choices of wafer chips may be widened, thus increasing a degree of freedom in design compared to conventional structures using POP and MCP components.

While example embodiments have been particularly shown and described, it will be understood by one of ordinary skill in the art that variations in form and detail may be made therein without departing from the spirit and scope of the claims.

What is claimed is:

1. A three-dimensional stack structure of wafer chips comprising:
a printed circuit board;
a first wafer chip mounted on the printed circuit board;
a second wafer chip stacked above the first wafer chip; and
first interposers interposed between the second wafer chip and the printed circuit board, the first interposers configured to electrically connect the second wafer chip to the printed circuit board.

2. The three-dimensional stack structure according to claim 1, wherein the first wafer chip is electrically connected to the printed circuit board by solder joints.

3. The three-dimensional stack structure according to claim 1, wherein the second wafer chip is electrically connected to the first interposers by solder joints.

4. The three-dimensional stack structure according to claim 1, wherein the printed circuit board includes one of an Si wafer substrate, a glass substrate and a low CTE organic substrate.

5. The three-dimensional stack structure according to claim 1, wherein the first interposers are formed of at least one of flame retardant 4 (FR4), silicon (Si), an epoxy mold compound (EMC) and glass.

6. The three-dimensional stack structure according to claim 1, wherein the first interposers include conductive vias so as to electrically connect the second wafer chip to the printed circuit board.

7. The three-dimensional stack structure according to claim 1, wherein the first interposers are electrically connected to the printed circuit board by at least one of solder joints, a conductive adhesive and an anisotropic adhesive.

8. The three-dimensional stack structure according to claim 1, wherein the first interposers include solder balls.

9. The three-dimensional stack structure according to claim 1, further comprising:
a third wafer chip stacked above the second wafer chip; and
second interposers interposed between the third wafer chip and the printed circuit board so as to electrically connect the third wafer chip to the printed circuit board.

10. The three-dimensional stack structure according to claim 9, wherein the third wafer chip is electrically connected to the second interposers by solder joints.

11. The three-dimensional stack structure according to claim 9, wherein the second interposers are formed of at least one of flame retardant 4 (FR4), silicon (Si), an epoxy mold compound (EMC) and glass.

12. The three-dimensional stack structure according to claim 9, wherein the second interposers include conductive vias so as to electrically connect the third wafer chip to the printed circuit board.

13. The three-dimensional stack structure according to claim 9, wherein the second interposers are electrically connected to the printed circuit board by at least one of solder joints, a conductive adhesive and an anisotropic adhesive.

14. A three-dimensional stack structure of wafer chips comprising:
a printed circuit board;
a first wafer chip mounted on the printed circuit board;
first interposers mounted on the printed circuit board outside a periphery of the first wafer chip; and
a second wafer chip mounted on the first interposers above the first wafer chip.

15. The three-dimensional stack structure according to claim 14, further comprising:
second interposers mounted on the printed circuit board outside a periphery defined by the first interposers; and
a third wafer chip mounted on the second interposers above the second wafer chip.
